(19) United States
(12) Patent Application Publication
(10) Pub. No.: US 2025/0287505 A1
(43) Pub. Date: Sep. 11, 2025

(54) SEMICONDUCTOR MODULE

(71) Applicant: SAMSUNG ELECTRONICS CO., LTD., Suwon-si (KR)

(72) Inventors: Jong-Hyun SEOK, Suwon-si (KR); Kang-Gyu LEE, Suwon-si (KR); Jeonghyeon CHO, Suwon-si (KR)

(21) Appl. No.: 18/829,011

(22) Filed: Sep. 9, 2024

(30) Foreign Application Priority Data
Mar. 8, 2024 (KR) 10-2024-0033468

(51) Int. Cl. H05K 1/18; H01L 25/065; H05K 1/02

(52) U.S. Cl. CPC H05K 1/181; H01L 25/0655; H05K 1/0256; H05K 2201/0397; H05K 2201/1034

(57) ABSTRACT

A semiconductor module includes a printed circuit board and a plurality of tab terminals on the printed circuit board. The plurality of tab terminals include a plurality of signal terminals and a plurality of ground terminals. The plurality of tab terminals are arranged in a first direction along a first edge of the printed circuit board, and each of the plurality of tab terminals extends in a second direction transverse to the first direction. Each of the plurality of signal terminals includes a first end portion adjacent to the first edge of the printed circuit board, and an insulation member on the printed circuit board. The insulation member includes an extension portion and a plurality of protruding portions. Each of the plurality of protruding portions covers the first end portion of a respective one of the plurality of signal terminals.

### CROSS-REFERENCE TO RELATED APPLICATION

This application claims priority to and the benefit of Korean Patent Application No. 10-2024-0033468 filed in the Korean Intellectual Property Office on Mar. 8, 2024, the disclosure of which is incorporated herein by reference in its entirety.

### BACKGROUND OF THE INVENTION

### (A) Field of the Invention

The present disclosure relates to a semiconductor module.

### (B) Description of the Related Art

The semiconductor module has a structure of connecting semiconductor chips and tab terminals, in that a semiconductor chip is disposed on a printed circuit board (PCB) corresponding to a substrate base, a tab terminal is disposed on a first edge of the printed circuit board, and wires are disposed on the printed circuit board. The semiconductor module may be mounted in a test socket of an automated test equipment (ATE) to perform a test for the semiconductor module, or it may be mounted in a socket of a main board to use the semiconductor module. The test socket of the automated test equipment (ATE) and the socket of the main board may include socket pins corresponding to the tab terminals of the semiconductor module, and when mounting the semiconductor module in the test socket of the automated test equipment (ATE) or mounting it in the socket of the main board, the socket pins may be electrically and physically connected to the tab terminals of the semiconductor module.

The test socket of the automated test equipment (ATE) or the socket of the main board before mounting the semiconductor module may be in a charged state, since charges moved from other electronic devices may be accumulated. While mounting the semiconductor module in the socket in the charged state, when a signal terminal among the tab terminals of the semiconductor module first contacts the socket pin of the socket, the charges accumulated in the socket move to the signal terminal of the semiconductor module through the socket pin, and move to the semiconductor chip through the signal terminal and signal wires. The socket, the socket pin, the signal terminal, and the signal wire form a discharge path, and the discharge path may damage an internal circuit of the semiconductor chip, and may be the cause for a product not operating properly, and may cause deterioration of signal integrity (SI).

### SUMMARY OF THE INVENTION

In a semiconductor module including tab terminals including signal terminals and ground terminals and being mountable in a socket, when mounting a semiconductor module on a socket, an end portion of each signal terminal may be covered by an insulation member such that the ground terminals may contact the socket pin of the socket before the signal terminals.

A semiconductor module including tab terminals including signal terminals and ground terminals and being mountable in a socket, an end portion of each signal terminal and a tie-bar extending from each signal terminal may be covered by an insulation member without removing tie-bars extending from tab terminals.

A semiconductor module may include a printed circuit board, and a plurality of tab terminals on the printed circuit board, where the plurality of tab terminals may include a plurality of signal terminals and a plurality of ground terminals, where the plurality of tab terminals are arranged in a first direction along a first edge of the printed circuit board, where each of the plurality of tab terminals extends in a second direction that is transverse to the first direction, and where each of the plurality of signal terminals may include a first end portion adjacent to the first edge of the printed circuit board, and a plurality of insulation members on the printed circuit board, where each of the plurality of insulation members covers the first end portion of a respective one of the plurality of signal terminals.

A semiconductor module may include a printed circuit board, a plurality of tab terminals on the printed circuit board, where the plurality of tab terminals may include a plurality of signal terminals and a plurality of ground terminals, where the plurality of tab terminals are arranged in a first direction along a first edge of the printed circuit board, where each of the plurality of tab terminals extends in a second direction that is transverse to the first direction, where each of the plurality of signal terminals may include first end portion adjacent to the first edge of the printed circuit board, and an insulation member on the printed circuit board, where the insulation member may include an extension portion extending in the first direction along the first edge of the printed circuit board, and a plurality of protruding portions extending in the second direction from the extension portion, and where each of the plurality of protruding portions covers the first end portion of a respective one of the plurality of signal terminals.

A semiconductor module may include a printed circuit board, a plurality of semiconductor chips on the printed circuit board, a plurality of tab terminals on the printed circuit board, where the plurality of tab terminals may include a plurality of signal terminals electrically connected to the plurality of semiconductor chips, and a plurality of ground terminals connected to a ground, where the plurality of tab terminals are arranged in a first direction along a first edge of the printed circuit board, where each of the plurality of tab terminals extends in a second direction that is transverse to the first direction and where each of the plurality of signal terminals may include a first end portion adjacent to the first edge of the printed circuit board, a plurality of first tie-bars on the printed circuit board, where each of the plurality of first tie-bars extends from a respective one of the plurality of signal terminals, a plurality of second tie-bars on the printed circuit board, where each of the plurality of second tie-bars extends from a respective one of the plurality of ground terminals, and a plurality of insulation members on the printed circuit board, where each of the plurality of insulation members covers the first end portion and the first tie-bar of a respective one of the plurality of signal terminals.

An end portion of each signal terminal may be covered with an insulation member such that the ground terminals may contact the socket pin of the socket before the signal terminals when mounting a semiconductor module in a socket. Accordingly, when mounting a semiconductor module in a socket, a discharge path along which the charge accumulated in the socket may move into a semiconductor chip through the socket, the socket pin, the signal terminal, and the signal wire, and potentially damage a circuit in the semiconductor chip may be removed, and the charge accumulated in the socket may be discharged to the ground through the ground terminals.

Without removing tie-bars extending from tab terminals, the end portion of each signal terminal and the tie-bar extending from each signal terminal may be covered with an insulation member. Accordingly, in the manufacturing process of the semiconductor module, a complex etching back process for removing tie-bars extending from tab terminals may be omitted, such that the turnaround time (TAT) of the semiconductor module manufacturing process may be reduced, and the manufacturing cost of the semiconductor module may be reduced.

### BRIEF DESCRIPTION OF THE DRAWINGS

FIG. 1 is a perspective view showing a semiconductor module aligned on a socket, in order to be mounted in the socket.

FIG. 2 is a cross-sectional view sequentially showing a process in which the semiconductor module of FIG. 1 is mounted in the socket of FIG. 1. The semiconductor module and socket of FIG. 2 is shown based on a cross-section of the semiconductor module and socket of FIG. 1 along line B-B′.

FIG. 3 is a perspective view showing a semiconductor module mounted in the socket.

FIG. 4 is an enlarged perspective view showing that tab terminals of region A of the semiconductor module of FIG. 1 are in contact with a socket pin of a socket when a semiconductor module is mounted in the socket.

FIG. 5 is a perspective view showing a semiconductor module of an embodiment.

FIG. 6 is an enlarged perspective view showing a region C of the semiconductor module of FIG. 5.

FIG. 7 is a cross-sectional view of the semiconductor module of FIG. 6 taken along line D-D′ and line E-E′.

FIG. 8 is a perspective view showing that tab terminals of region C of the semiconductor module of FIG. 5 are in contact with a socket pin of a socket when a semiconductor module of an embodiment is mounted in the socket.

FIG. 9 is a perspective view showing an exemplary variation of the semiconductor module of FIG. 5.

FIG. 10 is an enlarged perspective view showing a region F of the semiconductor module of FIG. 9.

FIG. 11 is a perspective view showing a semiconductor module of another embodiment.

FIG. 12 is an enlarged perspective view showing a region G of the semiconductor module of FIG. 11.

FIG. 13 is a cross-sectional view of the semiconductor module of FIG. 12 taken along line H-H′ and line I-I′.

FIG. 14 is a perspective view showing that tab terminals of region G of the semiconductor module of FIG. 11 are in contact with a socket pin of a socket when a semiconductor module of an embodiment is mounted in the socket.

FIG. 15 is a perspective view showing an exemplary variation of the

semiconductor module of FIG. 11.

FIG. 16 is an enlarged perspective view showing a region J of the semiconductor module of FIG. 15.

FIG. 17 is a perspective view showing a semiconductor module of still another embodiment.

FIG. 18 is an enlarged perspective view showing a region K of the semiconductor module of FIG. 17.

FIG. 19 is a cross-sectional view of the semiconductor module of FIG. 18 taken along line L-L′ and line M-M′.

FIG. 20 is a perspective view showing that tab terminals of region K of the semiconductor module of FIG. 17 are in contact with a socket pin of a socket when a semiconductor module of an embodiment is mounted in the socket.

FIG. 21 is a perspective view showing an exemplary variation of the semiconductor module of FIG. 17.

FIG. 22 is an enlarged perspective view showing a region N of the semiconductor module of FIG. 21.

### DETAILED DESCRIPTION OF THE EMBODIMENTS

Hereinafter, embodiments of the disclosure will be hereinafter described in detail with reference to the accompanying drawings, such that those skilled in the art may easily implement time. The disclosure may be implemented in various forms, and may not necessarily limited to embodiments described herein.

The drawings and description are to be regarded as illustrative in nature and not restrictive. Like reference numerals designate like elements throughout the specification.

Further, in the drawings, the size and thickness of each element may be arbitrarily illustrated for ease of description, and the present disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor module 10 of an embodiment will be described with reference to the drawings.

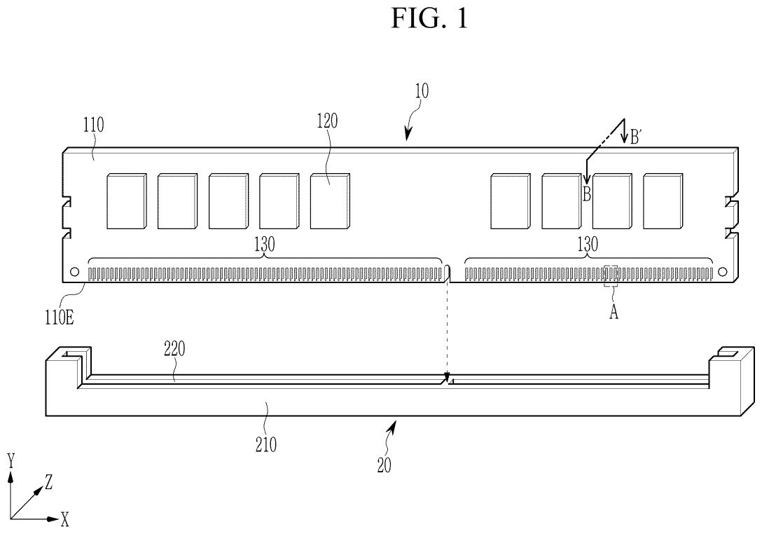

FIG. 1 is a perspective view showing the semiconductor module 10 aligned with the socket 20, in order to be mounted in a socket 20.

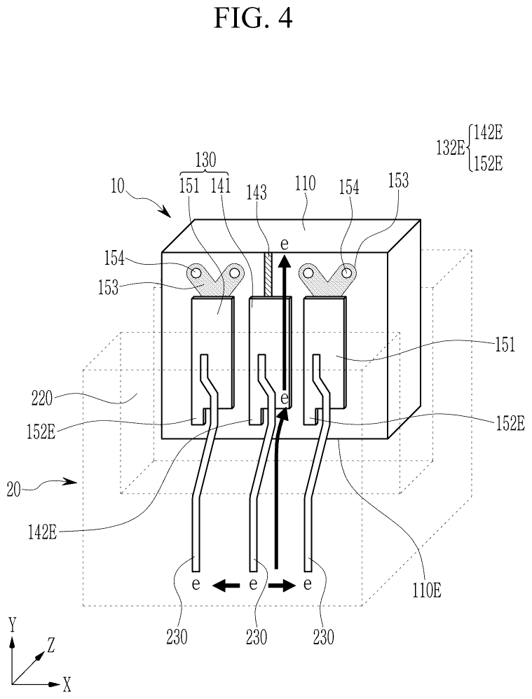

Referring to FIG. 1, the semiconductor module 10 may include a printed circuit board (PCB) 110, semiconductor chips 120, tab terminals 130, and tie-bars 132E (tie-bars of which a part is removed by an etch back process; refer to FIG. 4). In an embodiment, the semiconductor module 10 may include a memory module. In an embodiment, the semiconductor module 10 may include a dual In-line memory module (DIMM), small outline dual in-line memory module (SODIMM), unbuffered dual inline memory module (UDIMM), registered dual inline-memory module (RDIMM), load-reduced dual inline-memory module (LRDIMM), hypercloud dual inline-memory module (HDIMM), non-volatile DIMM (NVDIMM), fully buffered dual inline-memory module (FB-DIMM), CXL memory module (CMM), multi-ranked buffered DIMM (MRDIMM), or low-power compression attached memory module (LPCAMM).

The printed circuit board (PCB) 110 may be a substrate on which the semiconductor chips 120 are mounted. In an embodiment, the printed circuit board (PCB) 110 may have a multi-layer structure in which core layers and prepregs are alternately stacked, and a solder mask stacked in an uppermost portion and a lowermost portion. In an embodiment, core layers may include FR-4 and a metal trace attached to top and bottom sides of the FR-4.

Within the multi-layer structure, the printed circuit board (PCB) 110 may include a ground wire layer, a power wire layer, and a signal wire layer. The ground wire layer may be a bulk layer connected to the ground. The power wire layer may be a bulk layer connected to a power supply, and providing a path for supplying electric power the power supply. The signal wire layer may be a layer in which the wire patterns are formed. The ground wire layer, the power wire layer, and the signal wire layer may be disposed at different levels, and may be connected through vias.

The semiconductor chips 120 may be mounted on a surface of the printed circuit board (PCB) 110. The semiconductor chips 120 may be mounted on one surface or both surfaces of the printed circuit board (PCB) 110. In an embodiment, the semiconductor chips 120 may be linearly arranged along a first direction (X direction). In an embodiment, the semiconductor chips 120 may be mounted on the printed circuit board (PCB) 110 by a flip chip method. In an embodiment, a semiconductor chip 120 may be a memory chip or logic chip. In an embodiment, when a semiconductor chip 120 is a memory chip, the semiconductor chip 120 may include dynamic random-access memory (DRAM), static random-access memory (SRAM), Flash Memory, erasable programmable read-only memory (EPROM), phase change random-access memory (PRAM), magnetic random-access memory (MRAM), resistive random-access memory (RRAM), or spin-transfer torque magnetic random-access memory (STT-MRAM).

The tab terminals 130 may be disposed along a first edge 110E of the printed circuit board (PCB) 110. The tab terminals 130 may be disposed on both surfaces of the printed circuit board (PCB) 110. The tab terminals 130 may be arranged in the first direction (X direction) along a first edge of the printed circuit board (PCB) 110. Each of the tab terminals 130 may be spaced apart from the neighboring tab terminal 130 at a predetermined interval in the first direction (X direction). Each of the tab terminals 130 may extend in a second direction (Y direction) that is transverse to the first direction (X direction). In an embodiment, the tab terminal 130 may be formed by performing an electroplating process or electroless plating process. In an embodiment, the tab terminal 130 may include copper (Cu), nickel (Ni), or gold (Au).

The tab terminals 130 may include signal terminals 141, ground terminals 151, and power terminals (not shown). The signal terminals 141 may include a data terminal where data is input or output, an address terminal where an address signal is input, a command terminal where a command signal is input, a clock terminal where a clock signal is input, and a control terminal where a control signal is input. The signal terminals 141 may be electrically connected to the signal wire layer within the multi-layer structure of the printed circuit board (PCB) 110 and a signal wire line on a surface of the printed circuit board (PCB) 110. The ground terminals 151 may be electrically connected to the ground wire layer within the multi-layer structure of the printed circuit board (PCB) 110. Power terminals may be electrically connected to the power wire layer within the multi-layer structure of the printed circuit board (PCB) 110. In an embodiment, the tab terminals 130 may further include plating terminals or no-connection terminals.

Tie-bars 132E (refer to FIG. 4) may be disposed along the first edge 110E of the printed circuit board (PCB) 110. The tie-bars 132E may be disposed on both surfaces of the printed circuit board (PCB) 110. Each of the tie-bars 132E may extend from a first end of each of the tab terminals 130 toward the first edge 110E of the printed circuit board (PCB) 110. A first end of the tab terminal 130 may be defined as, among both ends of the tab terminal 130, an end at a location adjacent to the first edge 110E of the printed circuit board (PCB) 110. A second end of the tab terminal 130 may be defined as, among the both ends of the tab terminal 130, an end at a location distal to the first edge 110E of the printed circuit board (PCB) 110. The tie-bars 132E may be arranged in the first direction (X direction) along the first edge of the printed circuit board (PCB) 110. Each of the tie-bars 132E may be spaced apart from the neighboring tie-bar 132E at a predetermined interval in the first direction (X direction). Each of the tie-bars 132E may extend in the second direction (Y direction) that is transverse to the first direction (X direction).

The tie-bars 132E may serve to perform electroplating on the tab terminals 130 and wires. After the electroplating is performed, the tie-bars 132E are cut together while the flat plate pf the printed circuit board (PCB) 110 is cut, and in this case, when a line width of the tie-bars 132E in the first direction (X direction) is large, the tab terminals 130 may be damaged during the cutting process. Therefore, the tie-bar 132E may have a line width in the first direction (X direction) smaller than a line width of the tab terminal 130 in the first direction (X direction). Each of the tie-bars 132E may extend from a leftmost side portion, a rightmost side portion, or a portion between the leftmost side and the rightmost side of the first end of each of the tab terminals 130. In an embodiment, the tie-bar 132E may include copper (Cu), nickel (Ni), or gold (Au).

The semiconductor module 10 may include wires connecting the semiconductor chips 120, other elements (not shown), and the tab terminals 130. These wires may have any pattern on the printed circuit board (PCB) 110.

The socket 20 may be located on an automated test equipment (ATE) or a main board. The semiconductor module 10 may be mounted in the socket 20, and the socket 20 may couple and support the semiconductor module 10. The socket 20 may electrically connect the automated test equipment (ATE) and the semiconductor module 10 or the main board and the semiconductor module 10.

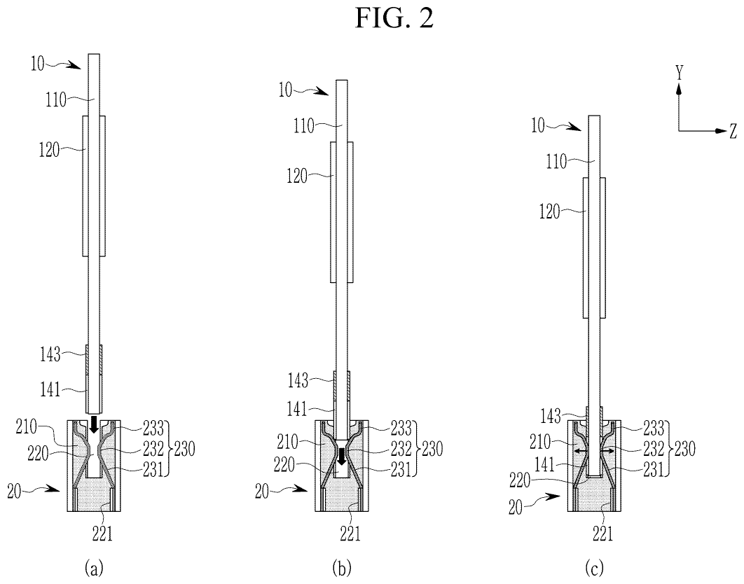

The socket 20 may include a frame 210, an insertion portion 220, and socket pins 230 (see FIG. 2). The frame 210 may support the semiconductor module 10. The frame 210 may be formed of an insulating material. In an embodiment, it may include plasma enhanced oxide (PEOX), tetraethyl orthosilicate (TEOS), boro tetraethyl orthosilicate (BTEOS), phosphorous tetraethyl orthosilicate (PTEOS), boro phospho tetraethyl orthosilicate (BPTEOS), boro silicate glass (BSG), phospho silicate glass (PSG), or boro-phospho-silicate glass (BPSG).

The insertion portion 220 may have a recessed structure such that the semiconductor module 10 inserted therein. A lower portion of the semiconductor module 10 may be inserted into the insertion portion 220. The tab terminals 130 of the semiconductor module 10 may be inserted into the insertion portion 220.

The socket pins 230 may be located on an inner side surface of the insertion portion 220 (see FIG. 2). The socket pins 230 may be arranged along the first direction (X direction). Each of the socket pins 230 may be spaced apart from the neighboring socket pin 230 at a predetermined interval in the first direction (X direction). Each of the socket pins 230 may extend in the second direction (Y direction) that is transverse to the first direction (X direction). Each of the socket pins 230 may correspond to each of the tab terminals 130. In an embodiment, the socket pin 230 may include at least one of copper (Cu), aluminum (AI), nickel (Ni), silver (Ag), gold (Au), platinum (Pt), tin (Sn), lead (Pb), titanium (Ti), chromium (Cr), palladium (Pd), indium (In), zinc (Zn) and carbon (C), or may include an alloy containing at least one thereof.

FIG. 2 is a cross-sectional view sequentially showing a process in which the semiconductor module 10 is mounted in the socket 20. The semiconductor module 10 and the socket 20 of FIG. 2 is shown based on a cross-section of the semiconductor module 10 and the socket 20 of FIG. 1 along line B-B′.

Referring to FIG. 2, a step (a) in which the semiconductor module 10 is aligned in the socket 20, a step (b) in which the semiconductor module 10 enters the insertion portion 220 of the socket 20 and starts to contact the socket pin 230, and a step (c) in which the semiconductor module 10 is mounted within the insertion portion 220 of the socket 20 may be sequentially performed.

The step (a) may be a step for aligning the semiconductor module 10 on the socket 20, in order to mount the semiconductor module 10 in the socket 20. The socket 20 may include a fixing portion 221 within the frame 210. The fixing portion 221 may secure the socket pin 230 to the frame 210. The socket pin 230 may extend in the second direction (Y direction). The socket pin 230 may include a first extension portion 231, a contact portion 232, and a second extension portion 233. A lower portion of the first extension portion 231 may be secured to the frame 210 by the fixing portion 221, and may be electrically connected to the automated test equipment (ATE) or the main board. As it goes upward, an upper portion of the first extension portion 231 may extend toward an insertion portion 220 of the socket 20. The contact portion 232 may be a portion to be in contact with the tab terminal 130 of the semiconductor module 10 mounted in the insertion portion 220 of the socket 20. As it goes upward, the second extension portion 233 may extend toward an exterior of the frame 210. The socket pins 230 may have elasticity (i.e., the socket pins 230 may flex or move during insertion of a semiconductor module 10 and then return to an unflexed state when the semiconductor module 10 is removed).

The step (b) may be a step in which the semiconductor module 10 enters the insertion portion 220 of the socket 20 and starts to contact the socket pin 230. The semiconductor module 10 may enter the insertion portion 220 while pushing the socket pin 230. Since the socket pin 230 has elasticity, the socket pin 230 may be pushed to move in an exterior direction of the frame 210 (represented by opposing arrows in FIG. 2), by the entrance of the semiconductor module 10. When the semiconductor module 10 starts to contact the contact portion 232, the contact portion 232 may start the contact at a lowermost portion of each of the tab terminals 130 of the semiconductor module 10.

The step (c) may be a step in which the entrance of the semiconductor module 10 into the insertion portion 220 of the socket 20 is completed. Since the socket pins 230 has elasticity, by the socket pins 230 being pushed to move in the exterior direction of the frame 210, the elastic force may act in an interior direction of the frame 210, such that the socket pins 230 may fix (i.e. grip and secure) the semiconductor module 10 within the frame 210.

In the present disclosure, although the socket 20 including the fixing portion 221 within the frame 210 and the socket pin 230 including the first extension portion 231, the contact portion 232, and the second extension portion 233 are illustrated and described, it is not limited thereto, and the socket 20 and the socket pin 230 having various shapes and structures may be included in the scope of the present disclosure.

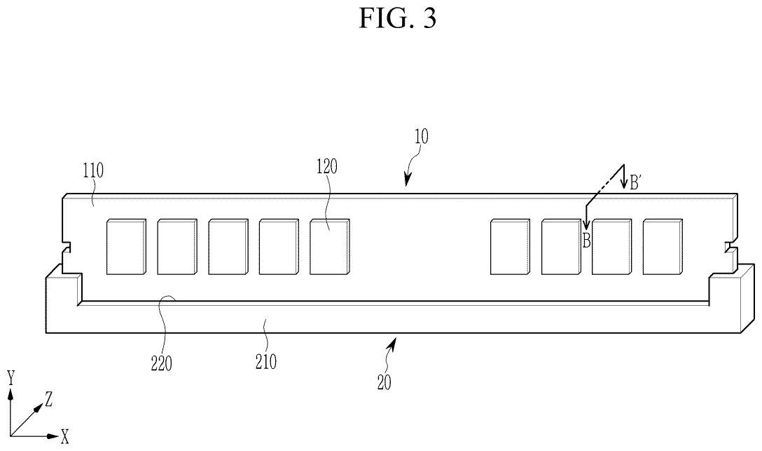

FIG. 3 is a perspective view showing the semiconductor module 10 mounted in the socket 20.

Referring to FIG. 3, the semiconductor module 10 may be mounted in the socket 20. The frame 210 of the socket 20 may support the semiconductor module 10. The semiconductor module 10 may be located within the insertion portion 220 of the socket 20. The socket pins 230 may fix the semiconductor module 10. The socket pins 230 may electrically connect the semiconductor module 10 to the automated test equipment (ATE) or the main board. Each of the socket pins 230 may correspond to each among the tab terminals 130 of the semiconductor module 10.

FIG. 4 is a perspective view showing that the tab terminals 130 of a region A of the semiconductor module 10 of FIG. 1 are in contact with the socket pin 230 of the socket 20 when the semiconductor module 10 is mounted in the socket 20.

The test socket of the automated test equipment (ATE) 20 or the socket 20 of the main board before mounting being the semiconductor module 10 may be in a charged state that the charge e moved from other electronic devices are accumulated. As such, when mounting the semiconductor module 10 in the socket 20 in the charged state, if the signal terminal 141 among the tab terminals 130 of the semiconductor module 10 first contacts the socket pin 230 of the socket 20 in the charged state, the charge e accumulated in the socket 20 may move to the signal terminal 141 of the semiconductor module 10 through the socket pin 230 in contact with the signal terminal 141, and may move to the semiconductor chip 120 via a signal wire 143 through the signal terminal 141. The socket 20, the socket pin 230, the signal terminal 141, and the signal wire 143 may form a discharge path, and the discharge path may damage a circuit within the semiconductor chip 120, which may be a cause to prevent the product from operating, or to deteriorate signal integrity (SI).

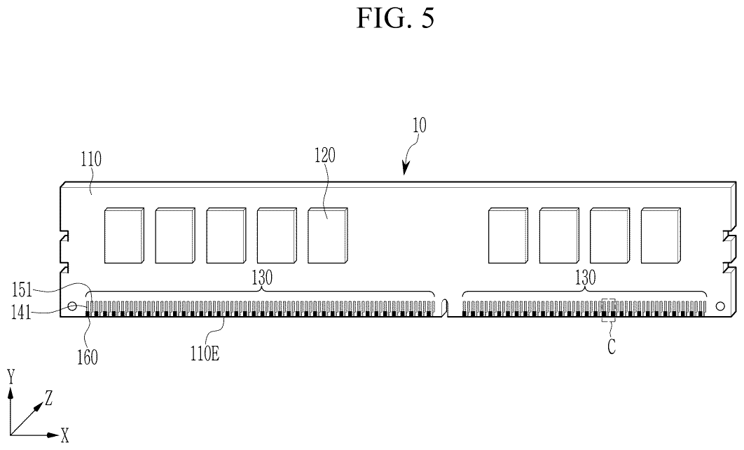

FIG. 5 is a perspective view showing the semiconductor module 10 of an embodiment.

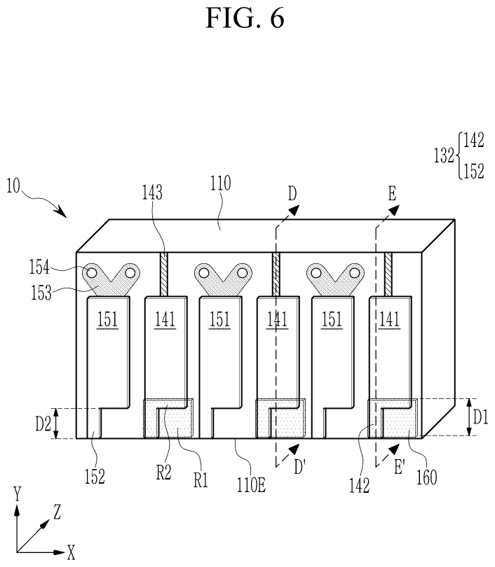

Referring to FIG. 5, the semiconductor module 10 may include insulation members 160. The insulation members 160 may be disposed on the printed circuit board (PCB) 110. Each of the insulation members 160 may cover a first end portion of each of the signal terminals 141 and a first tie-bar 142 (see FIG. 6) that extends from the first end portion and is not removed by the etch back process. The first end portion may be defined as a surface becoming to contact the socket pin 230 when the insulation member 160 is not present, located adjacent to the first edge 110E of the printed circuit board (PCB) 110, and having a predetermined area. The insulation members 160 may not cover a ground terminal, a power terminal, plating terminals, or no-connection terminals.

The insulation members 160 may be disposed along the first edge 110E of the printed circuit board (PCB) 110. The insulation members 160 may be disposed on both surfaces of the printed circuit board (PCB) 110. The insulation members 160 may be arranged in the first direction (X direction) along the first edge of the printed circuit board (PCB) 110. Each of the insulation members 160 may be spaced apart from the neighboring insulation member 160 at a predetermined interval in the first direction (X direction).

FIG. 6 is an enlarged perspective view showing a region C of the semiconductor module 10 of FIG. 5.

Referring to FIG. 6, the semiconductor module 10 may include the signal terminals 141 and the ground terminals 151 corresponding to a part of the tab terminals 130. The signal terminals 141 and the ground terminals 151 may be disposed on the printed circuit board (PCB) 110. The signal terminals 141 and the ground terminals 151 may be disposed along the first edge 110E of the printed circuit board (PCB) 110. The signal terminals 141 and the ground terminals 151 may be arranged in the first direction (X direction) along the first edge of the printed circuit board (PCB) 110. The signal terminal 141 may be spaced apart from the ground terminal 151 at a predetermined interval in the first direction (X direction). The signal terminals 141 and the ground terminals 151 may extend in the second direction (Y direction) that is transverse to the first direction (X direction). Each of the signal terminal 141 may have a first end and a second end. The first end may be defined as, among both ends of the signal terminal 141, an end at a location adjacent to the first edge 110E of the printed circuit board (PCB) 110. The second end may be defined as, among the both ends of the signal terminal 141, an end at a location distal to the first edge 110E of the printed circuit board (PCB) 110.

The semiconductor module 10 may include the tie-bars 132 that are not removed by the etch back process. The tie-bars 132 may include first tie-bars 142 and second tie-bars 152. The first tie-bars 142 and the second tie-bars 152 may be disposed on the printed circuit board (PCB) 110. The first tie-bar 142 may extend from a first end of the signal terminal 141 toward the first edge 110E of the printed circuit board (PCB) 110, to the first edge 110E of the printed circuit board (PCB) 110. The second tie-bar 152 may extend from a first end of the ground terminal 151 toward the first edge 110E of the printed circuit board (PCB) 110, to the first edge 110E of the printed circuit board (PCB) 110. The first tie-bars 142 and the second tie-bars 152 may be arranged in the first direction (X direction) along the first edge of the printed circuit board (PCB) 110. The first tie-bar 142 may be spaced apart from the second tie-bar 152 at a predetermined interval in the first direction (X direction). The first tie-bars 142 and the second tie-bars 152 may extend in the second direction (Y direction) that is transverse to the first direction (X direction). The first tie-bar 142 may have a line width in the first direction (X direction) smaller than a line width of the signal terminal 141 in the first direction (X direction). The second tie-bar 152 may have a line width in the first direction (X direction) smaller than a line width of the ground terminal 151 in the first direction (X direction). The first tie-bar 142 may extend from a leftmost side portion, a rightmost side portion, or a portion between the leftmost side and rightmost side of the first end of the signal terminal 141. The second tie-bar 152 may extend from a leftmost side portion, a rightmost side portion, or a portion between the leftmost side and rightmost side of the first end of the ground terminal 151.

In the manufacturing process of the semiconductor module 10, the etch back process may be performed in order to remove the tie-bars 132 extending from the tab terminals 130. The etch back process may be formed by complex processes of forming a photoresist, forming a photoresist pattern by exposing and developing the formed photoresist, etching tie-bars, and removing the photoresist pattern. The etch back process is performed through various processes, such that the turnaround time (TAT) is long, and the manufacturing cost of the semiconductor module is increased.

According to the present disclosure, without removing the tie-bars 132 extending from the tab terminals 130, the first tie-bar 142 extending from a first end portion of each signal terminal 141 may be covered with the insulation member 160. Accordingly, in the manufacturing process of the semiconductor module 10, the complex etch back process for removing the tie-bars 132 extending from the tab terminals 130 may be omitted. Therefore, the turnaround time (TAT) required for manufacturing the semiconductor module 10 may be reduced, and may reduce manufacturing cost of the semiconductor module 10.

The semiconductor module 10 may include signal wires 143. The signal wires 143 may be disposed on the printed circuit board (PCB) 110. The signal wire 143 may extend from a second end of the signal terminal 141 in a direction toward the semiconductor chip 120.

The semiconductor module 10 may include ground wires 153. The ground wires 153 may be disposed on the printed circuit board (PCB) 110. The ground wire 153 may extend from a second end of the ground terminal 151 in a direction toward a via hole 154. Via holes 154 may be connected to the ground wire layer within the printed circuit board (PCB) 110.

The semiconductor module 10 may include the insulation members 160. The insulation members 160 may be disposed on the printed circuit board (PCB) 110. Each of the insulation members 160 may cover the first end portion of each of the signal terminals 141 and the first tie-bar 142 that is not removed by the etch back process. The insulation members 160 may not cover a ground terminal, a power terminal, plating terminals or no-connection terminals. The insulation members 160 may be spaced apart from the ground terminal, power terminal, plating terminals or no-connection terminals. The insulation members 160 may be disposed along the first edge 110E of the printed circuit board (PCB) 110, as illustrated. The insulation members 160 may be arranged in the first direction (X direction) along the first edge of the printed circuit board (PCB) 110.

Each of the insulation members 160 may include a first region R1 and a second region R2 defined by dividing a plane of each insulation member 160. The first region R1 of the insulation member 160 may contact the printed circuit board (PCB) 110. The second region R2 of the insulation member 160 may contact the signal terminal 141. The second region R2 of the insulation member 160 may be on and cover the first tie-bar 142 that is not removed by the etch back process and the first end portion of the signal terminal 141.

Each of the signal terminals 141 may include a first surface exposed to the air (i.e., the first surface is exposed to the external environment and not covered by anything). Each of the ground terminals 151 may include a second surface exposed to the air (i.e., the second surface is exposed to the external environment and not covered by anything). The first surface and the second surface may be a flat surface defined by the first direction (X direction) and the second direction (Y direction). Since the first end portion of the signal terminal 141 is covered by the insulation member 160 and the ground terminal 151 is not covered by the insulation member 160, the area of the first surface may be smaller than the area of the second surface. A first length D1 in the second direction (Y direction) from the first edge 110E of the printed circuit board (PCB) 110 to the exposed first surface is longer than a second length D2 in the second direction (Y direction) from the first edge 110E of the printed circuit board (PCB) 110 to the exposed second surface.

The insulation members 160 may be formed of a material that may withstand the force when inserting the semiconductor module 10 into the socket 20, and may not cause a defect (e.g., appearance change of the insulation member 160, crack occurrence of the insulation member 160, or exposing the signal terminal due to losing of at least a portion of the insulation member 160) when repeatedly inserting the semiconductor module 10 into the socket 20. In an embodiment, the insulation members 160 may include a photo solder resist (PSR). The PSR may be an insulation material used in the manufacturing process of the printed circuit board (PCB) 110, and configured to coat the surface of the printed circuit board (PCB) 110 to protect the circuit. In an embodiment, the insulation members 160 may include an overcoating material. The overcoating material may be a material that may improve mechanical strength by being applied to the device to prevent damage. In an embodiment, overcoating material may include polyurethane acrylate, urethane acrylate, acrylic, modified acrylate, or epoxy.

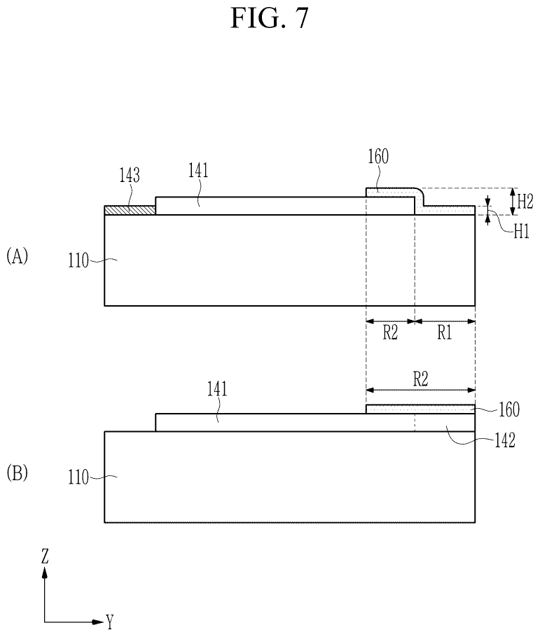

FIG. 7 is a cross-sectional view of the semiconductor module 10 of FIG. 6 taken along line D-D′ and line E-E′. Section (A) shows a cross-section of the semiconductor module 10 of FIG. 6 taken along line D-D′, and section (B) shows a cross-section of the semiconductor module 10 of FIG. 6 taken along line E-E′.

Referring to FIG. 7, in section (A), the signal terminal 141, the signal wire 143 and the insulation member 160 may be disposed on the printed circuit board (PCB) 110. The insulation member 160 may include the first region R1 covering the printed circuit board (PCB) 110 and the second region R2 covering a first end portion of the signal terminal 141. The first region R1 of the insulation member 160 may be located at a first level, and the second region R2 of the insulation member 160 may be located at a second level that is higher than the first level. With reference to a contact surface of the printed circuit board (PCB) 110 and the insulation member 160, the surface of the insulation member 160 may have a first height H1 in the first region R1, and the surface of the insulation member 160 may have a second height H2 higher than the first height H1 in the second region R2. In other words, a surface of the first region is located at a first level relative to the contact surface of the PCB 110, a surface of the second region is located at a second level relative to the contact surface of the PCB 110, and the second level is further outward (i.e., along the Z direction) from the contact surface of the PCB 110 than the first level.

In section (B), the signal terminal 141, the first tie-bar 142 that is not removed by the etch back process, and the insulation member 160 may be disposed on the printed circuit board (PCB) 110. The insulation member 160 may include the second region R2 that covers the first end portion of the signal terminal 141 and the first tie-bar 142 that are not removed by the etch back process.

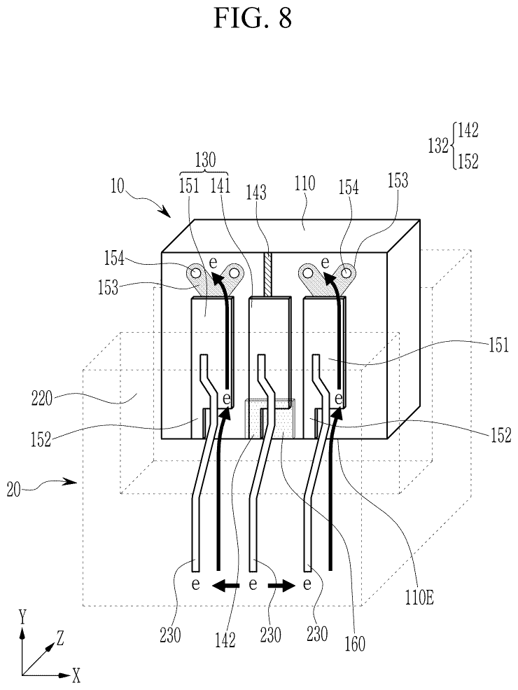

FIG. 8 is a perspective view showing that the tab terminals 130 of the region C of the semiconductor module 10 of FIG. 5 are in contact with the socket pin 230 of the socket 20 when the semiconductor module 10 of an embodiment is mounted in the socket 20.

Referring to FIG. 8, the first end portion of the signal terminal 141 may be covered by the insulation member 160, and the ground terminal 151 may not be covered by the insulation member 160. Therefore, when mounting the semiconductor module 10 in the socket 20 in the charged state, the ground terminal 151 or the second tie-bar 152 that is not cover by the insulation member 160 may contact the socket pin 230 of the socket 20 earlier than the signal terminal 141 of which the first end portion is cover by the insulation member 160. The charge e accumulated in the socket 20 may move to the ground terminal 151 of the semiconductor module 10 through the socket pin 230 in contact with the ground terminal 151 or the second tie-bar 152, move to the via hole 154 via the ground wire 153 through the ground terminal 151, and exit to the ground through the ground wire layer of the printed circuit board (PCB) 110. The discharge path may be formed as a path passing through the socket 20, the socket pin 230, the ground terminal 151 (or the ground terminal 151 through the second tie-bar 152), the ground wire 153, the via hole 154, the ground wire layer, and the ground. Therefore, according to the present disclosure, since the discharge path leading to the ground is formed, the charge e accumulated in the socket 20 may be prevented from moving to the semiconductor chip 120, thereby damaging a circuit within the semiconductor chip 120, and deteriorating the signal integrity (SI).

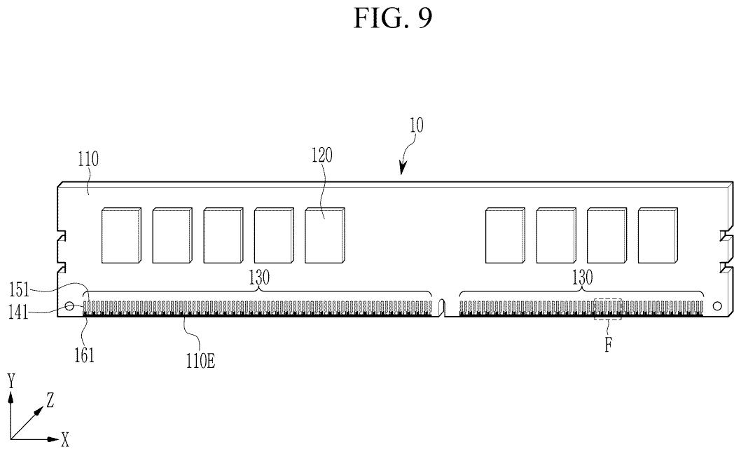

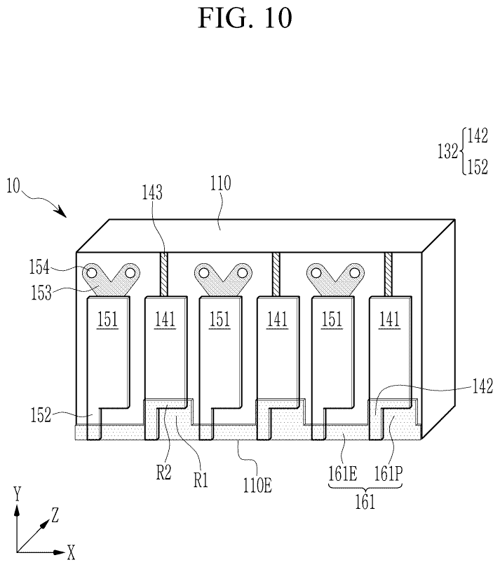

FIG. 9 is a perspective view showing an exemplary variation of the semiconductor module 10 of FIG. 5. FIG. 10 is an enlarged perspective view showing a region F of the semiconductor module 10 of FIG. 9.

Referring to FIG. 9 and FIG. 10, the semiconductor module 10 may include an insulation member 161. The insulation member 161 may be disposed on the printed circuit board (PCB) 110. The insulation member 161 may not cover a ground terminal, a power terminal, plating terminals or no-connection terminals. The insulation member 161 may be spaced apart from the ground terminal, power terminal, plating terminals or no-connection terminals. The insulation member 161 may be disposed along the first edge 110E of the printed circuit board (PCB) 110.

The insulation member 161 may include an extension portion 161E and protruding portions 161P. The extension portion 161E may extend in the first direction (X direction) along the first edge 110E of the printed circuit board (PCB) 110. The extension portion 161E may be located between the tab terminals 130 and the first edge 110E of the printed circuit board (PCB) 110. The extension portion 161E may contact the printed circuit board (PCB) 110 and the tie-bars 132 that are not removed by the etch back process. The extension portion 161E may cover a portion of each of the tie-bars 132 that are not removed by the etch back process. The extension portion 161E may be spaced apart from the tab terminals 130. The extension portion 161E may be spaced apart from the signal terminals 141 and the ground terminals 151.

The protruding portions 161P may extend in the second direction (Y direction) from the extension portion 161E. The protruding portions 161P may be integrally formed with the extension portion 161E. The protruding portions 161P may be disposed with a step in the second direction (Y direction) with respect to the extension portion 161E (i.e., the protruding portions 161P extend above the extension portions 161E along the Y direction). The protruding portions 161P may be arranged in the first direction (X direction) along the first edge 110E of the printed circuit board (PCB) 110. Each of the protruding portions 161P may contact the printed circuit board (PCB) 110, the signal terminal 141, and the first tie-bar 142 that is not removed by the etch back process. Each of the protruding portions 161P may cover a first end portion of the signal terminal 141 and a portion of the first tie-bar 142 that is not removed by the etch back process. The first end portion may be defined as a surface becoming to contact the socket pin 230 when the insulation member 160 is not present, located adjacent to the first edge 110E of the printed circuit board (PCB) 110, and having a predetermined area. The protruding portions 161P may be spaced apart from the ground terminals 151. Each of the protruding portions 161P may be spaced apart from the neighboring protruding portion 161P at a predetermined interval in the first direction (X direction). Each of the protruding portions 161P may include the first region R1 and the second region R2 defined by dividing a plane of the protruding portion 161P. The first region R1 may contact the printed circuit board (PCB) 110. The second region R2 may contact the first end portion of the signal terminal 141 and the first tie-bar 142 that is not removed by the etch back process.

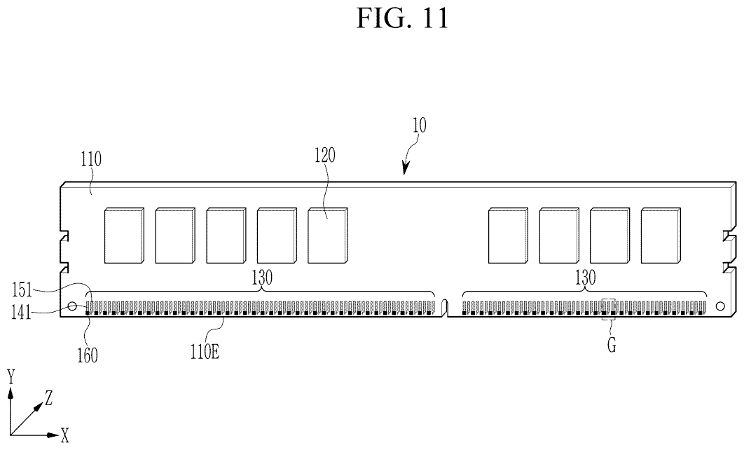

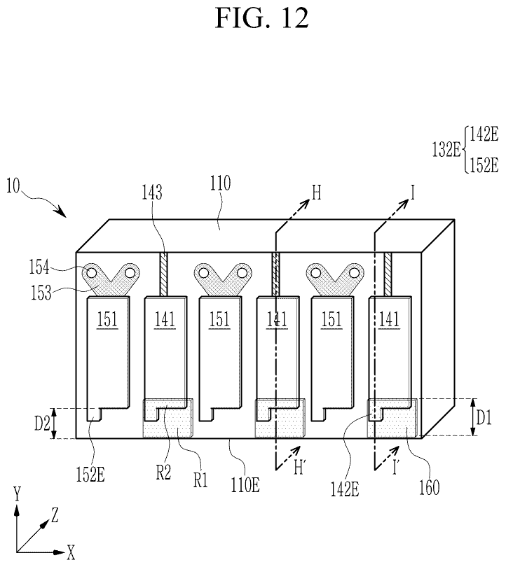

FIG. 11 is a perspective view showing the semiconductor module 10 of another embodiment. FIG. 12 is an enlarged perspective view showing a region G of the semiconductor module 10 of FIG. 11.

Referring to FIG. 11 and FIG. 12, the semiconductor module 10 may include the insulation members 160. Each of the insulation members 160 may cover a first end portion of each of the signal terminals 141 and a first tie-bar 142E that extends from the first end portion and of which a portion is removed by the etch back process.

The semiconductor module 10 may include a plurality of tie-bars 132E of which a portion is removed by the etch back process. The tie-bars 132E of which a portion is removed by the etch back process may include the first tie-bars 142E and the second tie-bars 152E. The first tie-bars 142E and the second tie-bars 152E may be disposed on the printed circuit board (PCB) 110. The first tie-bar 142E may extend from the first end of the signal terminal 141 toward the first edge 110E of the printed circuit board (PCB) 110. The second tie-bar 152E may extend from the first end of the ground terminal 151 toward the first edge 110E of the printed circuit board (PCB) 110. The first tie-bars 142E and the second tie-bars 152E may be arranged in the first direction (X direction) along the first edge of the printed circuit board (PCB) 110.

The semiconductor module 10 may include the insulation members 160. Each of the insulation members 160 may include the first region R1 and the second region R2 defined by dividing the plane of each insulation member 160. The first region R1 of the insulation member 160 may contact the printed circuit board (PCB) 110. The second region R2 of the insulation member 160 may contact the signal terminal 141. The second region R2 of the insulation member 160 may cover the first end portion of the signal terminal 141 and the first tie-bar 142E of which a portion is removed by the etch back.

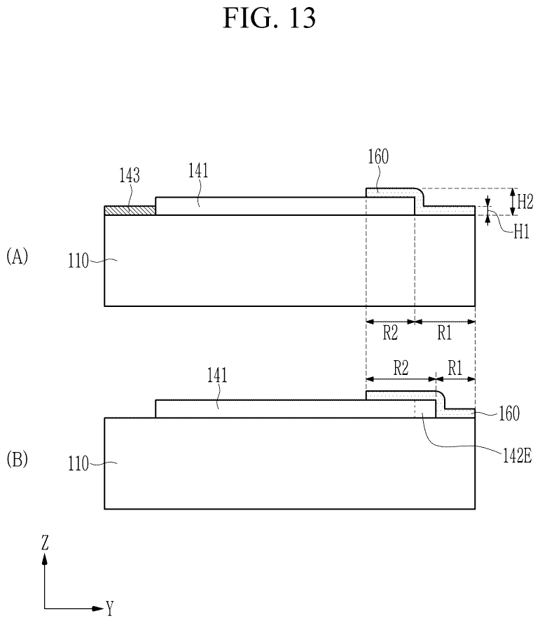

FIG. 13 is a cross-sectional view of the semiconductor module 10 of FIG. 12 taken along line H-H′ and line I-I′. Section (A) shows a cross-section of the semiconductor module 10 of FIG. 12 taken along line H-H′, and section (B) shows a cross-section of the semiconductor module 10 of FIG. 12 taken along line I-I′.

Referring to FIG. 13, in section (A), the signal terminal 141, the signal wire 143 and the insulation member 160 may be disposed on the printed circuit board (PCB) 110. The insulation member 160 may include the first region R1 covering the printed circuit board (PCB) 110 and the second region R2 covering the first end portion of the signal terminal 141. The first region R1 of the insulation member 160 may be located at a first level, and the second region R2 of the insulation member 160 may be located at a second level that is higher than the first level. In other words, a surface of the first region is located at a first level relative to the contact surface of the PCB 110, a surface of the second region is located at a second level relative to the contact surface of the PCB 110, and the second level is further outward (i.e., along the Z direction) from the contact surface of the PCB 110. With reference to the contact surface of the printed circuit board (PCB) 110 and the insulation member 160, the surface of the insulation member 160 may have the first height H1 in the first region R1, and the surface of the insulation member 160 may have the second height H2 higher than the first height H1 in the second region R2.

In section (B), the signal terminal 141, the first tie-bar 142E of which a portion is removed by the etch back process, and the insulation member 160 may be disposed on the printed circuit board (PCB) 110. The insulation member 160 may include the first region R1 covering the printed circuit board (PCB) 110 and the second region R2 covering cover the first end portion the signal terminal 141 and the first tie-bar 142E of which a portion is removed by the etch back process.

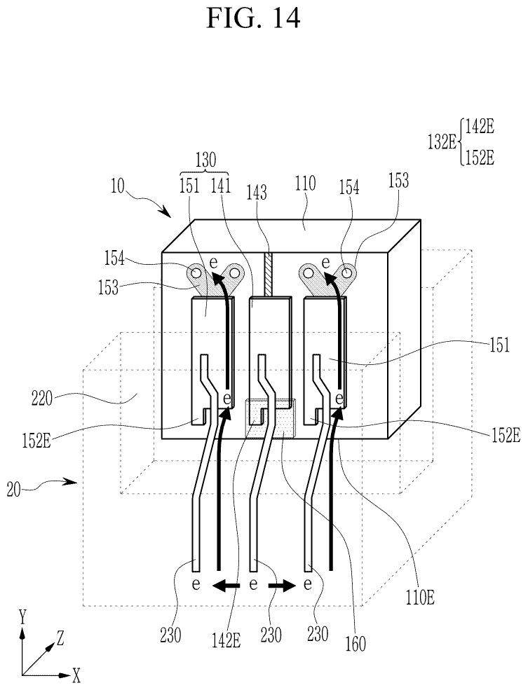

FIG. 14 is a perspective view showing that the tab terminals 130 of the region G of the semiconductor module 10 of FIG. 11 are in contact with the socket pin 230 of the socket 20 when the semiconductor module 10 of an embodiment is mounted in the socket 20.

Referring to FIG. 14, the first end portion of the signal terminal 141 and the first tie-bar 142E of which a portion is removed by the etch back process may be covered by the insulation member 160, and the ground terminal 151 and the second tie-bar 152E of which a portion is removed by the etch back process may not be covered by the insulation member 160. Therefore, when mounting the semiconductor module 10 in the socket 20 in the charged state, the ground terminal 151 or the second tie-bar 152E that is not cover by the insulation member 160 may contact the socket pin 230 of the socket 20 earlier than the signal terminal 141 of which the first end portion is cover by the insulation member 160. The charge e accumulated in the socket 20 may move to the ground terminal 151 of the semiconductor module 10 through the socket pin 230 in contact with the ground terminal 151 or the second tie-bar 152E, move to the via hole 154 via the ground wire 153 through the ground terminal 151, and exit to the ground through the ground wire layer of the printed circuit board (PCB) 110. The discharge path may be formed as a path passing through the socket 20, the socket pin 230, the ground terminal 151 (or the ground terminal 151 through the second tie-bar 152E), the ground wire 153, the via hole 154, the ground wire layer, and the ground. Therefore, according to the present disclosure, since the discharge path leading to the ground is formed, the charge e accumulated in the socket 20 may be prevented from moving to the semiconductor chip 120, thereby damaging a circuit within the semiconductor chip 120, and deteriorating the signal integrity (SI).

In addition to the above-described content, contents shown in and described with reference to FIG. 5 to FIG. 8 may be equally applied to features with respect to FIG. 11 to FIG. 14.

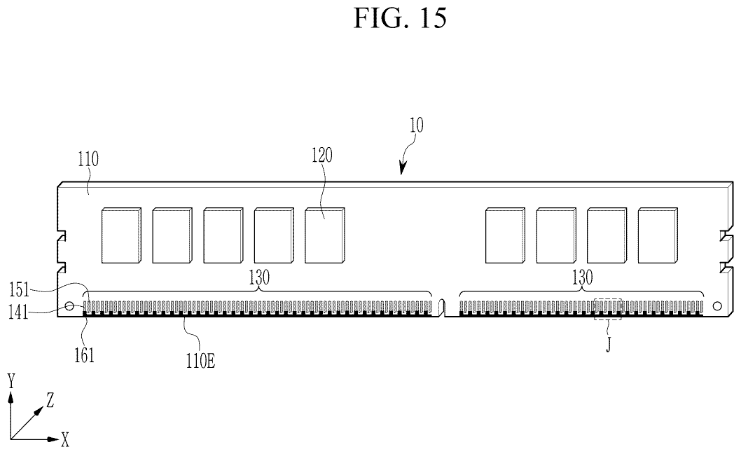

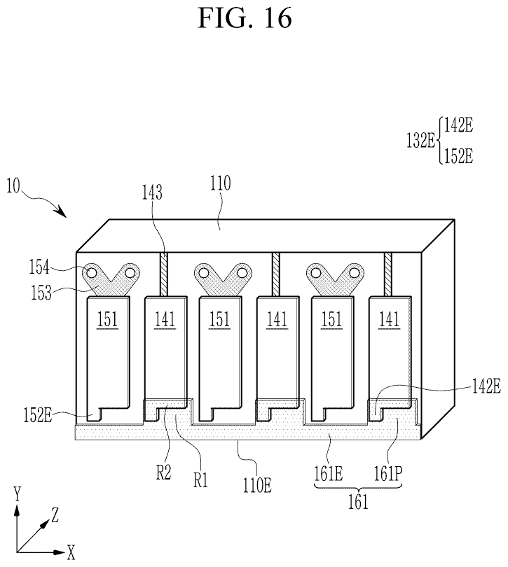

FIG. 15 is a perspective view showing an exemplary variation of the semiconductor module 10 of FIG. 11. FIG. 16 is an enlarged perspective view showing a region J of the semiconductor module 10 of FIG. 15.

Referring to FIG. 15 and FIG. 16, the semiconductor module 10 may include the insulation member 161. The insulation member 161 may be disposed on the printed circuit board (PCB) 110. The insulation member 161 may not cover a ground terminal, a power terminal, plating terminals or no-connection terminals. The insulation member 161 may be spaced apart from the ground terminal, power terminal, plating terminals or no-connection terminals. The insulation member 161 may be disposed along the first edge 110E of the printed circuit board (PCB) 110.

The insulation member 161 may include the extension portion 161E and the protruding portions 161P. The extension portion 161E may extend in the first direction (X direction) along the first edge 110E of the printed circuit board (PCB) 110. The extension portion 161E may be located between the tab terminals 130 and the first edge 110E of the printed circuit board (PCB) 110, as illustrated. The extension portion 161E may contact the printed circuit board (PCB) 110. The extension portion 161E may be spaced apart from the tab terminals 130. The extension portion 161E may be spaced apart from the signal terminals 141 and the ground terminals 151.

The protruding portions 161P may extend in the second direction (Y direction) from the extension portion 161E. The protruding portions 161P may be integrally formed with the extension portion 161E. The protruding portions 161P may be disposed with a step in the second direction (Y direction) with respect to the extension portion 161E (i.e., the protruding portions 161P extend above the extension portion 161E along the Y direction). The protruding portions 161P may be arranged in the first direction (X direction) along the first edge 110E of the printed circuit board (PCB) 110. Each of the protruding portions 161P may contact the printed circuit board (PCB) 110, the signal terminal 141, and the first tie-bar 142E of which a portion is removed by the etch back process. Each of the protruding portions 161P may cover the first end portion of the signal terminal 141 and the first tie-bar 142E of which a portion is removed by the etch back process. The first end portion may be defined as a surface that contacts the socket pin 230 when the insulation member 160 is not present, located adjacent to the first edge 110E of the printed circuit board (PCB) 110, and having a predetermined area. The protruding portions 161P may be spaced apart from the ground terminals 151. Each of the protruding portions 161P may be spaced apart from a neighboring protruding portion 161P at a predetermined interval in the first direction (X direction). Each of the protruding portions 161P may include the first region R1 and the second region R2 defined by dividing the plane of the protruding portion 161P. The first region R1 may contact the printed circuit board (PCB) 110. The second region R2 may contact the first end portion of the signal terminal 141 and the first tie-bar 142E of which a portion is removed by the etch back process.

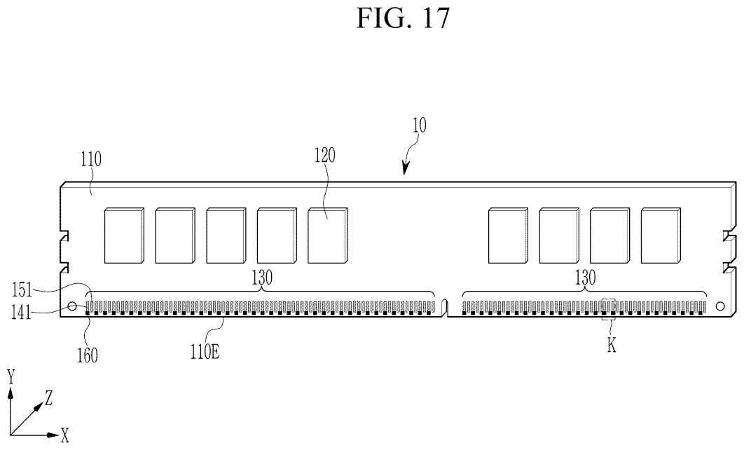

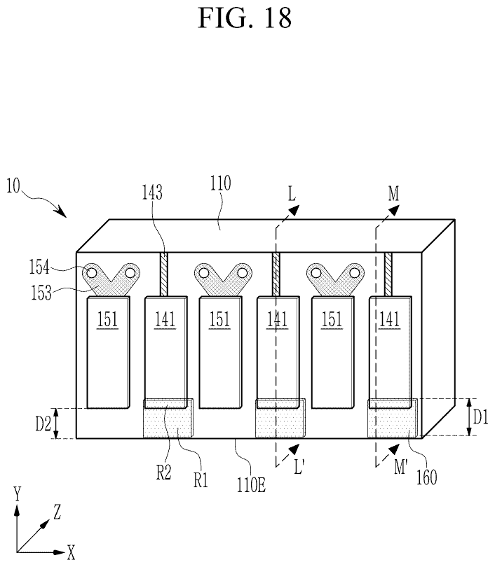

FIG. 17 is a perspective view showing the semiconductor module 10 of still another embodiment. FIG. 18 is an enlarged perspective view showing a region K of the semiconductor module 10 of FIG. 17.

Referring to FIG. 17 and FIG. 18, the semiconductor module 10 may include the insulation members 160. Each of the insulation members 160 may cover the first end portion of each of the signal terminals 141.

The semiconductor module 10 may not include the tie-bars 132 and the tie-bars 132E of which a portion is removed by the etch back process. In an embodiment, the tab terminals 130 may be formed by performing an electroless plating process without the tie-bars 132 and the tie-bars 132E of which a portion is removed by the etch back process. The semiconductor module 10 may include the insulation members 160. Each of the insulation members 160 may include the first region R1 and the second region R2 defined by dividing the plane of each insulation member 160. The first region R1 of the insulation member 160 may contact the printed circuit board (PCB) 110. The second region R2 of the insulation member 160 may contact the signal terminal 141. The second region R2 of the insulation member 160 may cover the first end portion of the signal terminal 141.

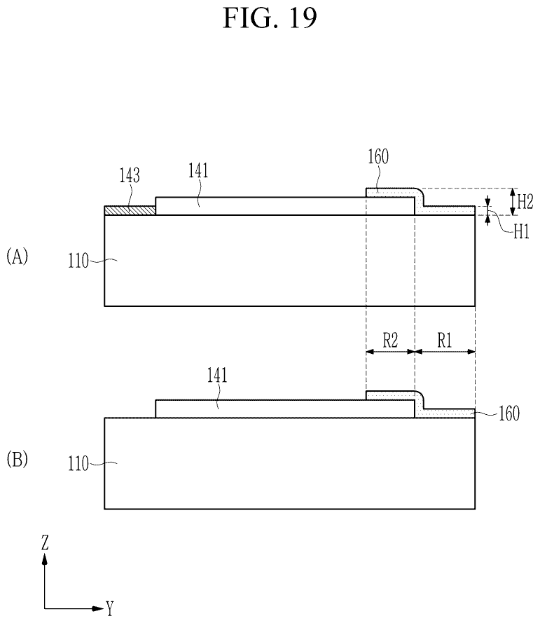

FIG. 19 is a cross-sectional view of the semiconductor module 10 of FIG. 18 taken along line L-L′ and line M-M′. Section (A) shows a cross-section of the semiconductor module 10 of FIG. 18 taken along line L-L′, and section (B) shows a cross-section of the semiconductor module 10 of FIG. 18 taken along line M-M′.

Referring to FIG. 19, in section (A), the signal terminal 141, the signal wire 143 and the insulation member 160 may be disposed on the printed circuit board (PCB) 110, and in section (B), the signal terminal 141 and the insulation member 160 may be disposed on the printed circuit board (PCB) 110. The insulation member 160 may include the first region R1 covering the printed circuit board (PCB) 110 and the second region R2 covering the first end portion of signal terminal 141. The first region R1 of the insulation member 160 may be located at a first level, and the second region R2 of the insulation member 160 may be located at a second level that is higher than the first level. In other words, a surface of the first region is located at a first level relative to the contact surface of the PCB 110, a surface of the second region is located at a second level relative to the contact surface of the PCB 110, and the second level is further outward (i.e., along the Z direction) from the contact surface of the PCB 110 than the first level. With reference to the contact surface of the printed circuit board (PCB) 110 and the insulation member 160, the surface of the insulation member 160 may have the first height H1 in the first region R1, and the surface of the insulation member 160 may have the second height H2 higher than the first height H1 in the second region R2.

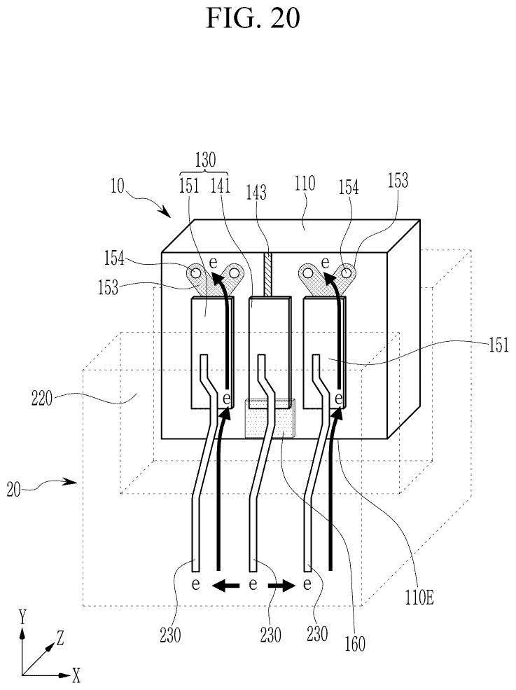

FIG. 20 is a perspective view showing that the tab terminals 130 of the region K of the semiconductor module 10 of FIG. 17 are in contact with the socket pin 230 of the socket 20 when the semiconductor module 10 of an embodiment is mounted in the socket 20.

Referring to FIG. 20, the first end portion of the signal terminal 141 may be covered by the insulation member 160, and the ground terminal 151 may not be covered by the insulation member 160. Therefore, when mounting the semiconductor module 10 in the socket 20 in the charged state, the ground terminal 151 that is not cover by the insulation member 160 may contact the socket pin 230 of the socket 20 earlier than the signal terminal 141 of which the first end portion is cover by the insulation member 160. The charge e accumulated in the socket 20 may move to the ground terminal 151 of the semiconductor module 10 through the socket pin 230 in contact with the ground terminal 151, move to the via hole 154 via the ground wire 153 through the ground terminal 151, and exit to the ground through the ground wire layer of the printed circuit board (PCB) 110. The discharge path may be formed as a path passing through the socket 20, the socket pin 230, the ground terminal 151, the ground wire 153, the via hole 154, the ground wire layer, and the ground. Therefore, according to the present disclosure, since the discharge path leading to the ground is formed, the charge e accumulated in the socket 20 may be prevented from moving to the semiconductor chip 120, thereby damaging a circuit within the semiconductor chip 120, and deteriorating the signal integrity (SI).

In addition to the above-described content, contents shown in and described with reference to FIG. 5 to FIG. 8 may be equally applied to features with respect to FIG. 17 to FIG. 20.

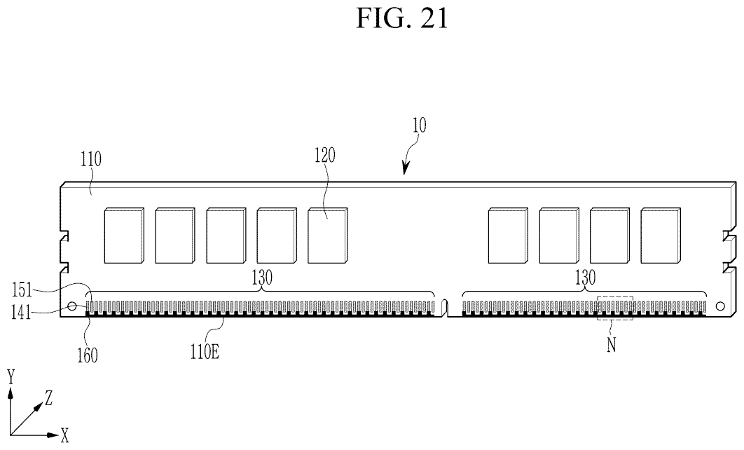

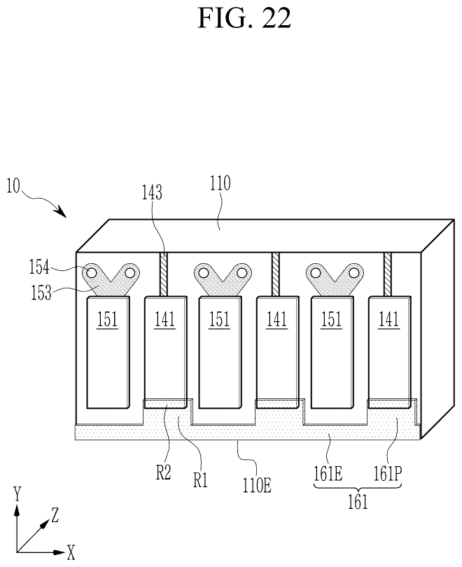

FIG. 21 is a perspective view showing an exemplary variation of the semiconductor module 10 of FIG. 17. FIG. 22 is an enlarged perspective view showing a region N of the semiconductor module 10 of FIG. 21.

Referring to FIG. 21 and FIG. 22, the semiconductor module 10 may include the insulation member 161. The insulation member 161 may be disposed on the printed circuit board (PCB) 110. The insulation member 161 may not cover a ground terminal, a power terminal, plating terminals or no-connection terminals. The insulation member 161 may be spaced apart from the ground terminal, power terminal, plating terminals or no-connection terminals. The insulation member 161 may be disposed along the first edge 110E of the printed circuit board (PCB) 110.

The insulation member 161 may include the extension portion 161E and the protruding portions 161P. The extension portion 161E may extend in the first direction (X direction) along the first edge 110E of the printed circuit board (PCB) 110. The extension portion 161E may be located between the tab terminals 130 and the first edge 110E of the printed circuit board (PCB) 110. The extension portion 161E may contact the printed circuit board (PCB) 110. The extension portion 161E may be spaced apart from the tab terminals 130, as illustrated. The extension portion 161E may be spaced apart from the signal terminals 141 and the ground terminals 151.

The protruding portions 161P may extend in the second direction (Y direction) from the extension portion 161E. The protruding portions 161P may be integrally formed with the extension portion 161E. The protruding portions 161P may be disposed with a step in the second direction (Y direction) with respect to the extension portion 161E (i.e., the protruding portions 161P extend above the extension portion 161E along the Y direction). The protruding portions 161P may be arranged in the first direction (X direction) along the first edge 110E of the printed circuit board (PCB) 110. Each of the protruding portions 161P may contact the printed circuit board (PCB) 110, and the signal terminal 141. Each of the protruding portions 161P may cover the first end portion of the signal terminal 141. The first end portion may be defined as a surface that contacts the socket pin 230 when the insulation member 160 is not present, located adjacent to the first edge 110E of the printed circuit board (PCB) 110, and having a predetermined area. The protruding portions 161P may be spaced apart from the ground terminals 151. Each of the protruding portions 161P may be spaced apart from the neighboring protruding portion 161P at a predetermined interval in the first direction (X direction). Each of the protruding portions 161P may include the first region R1 and the second region R2 defined by dividing the plane of the protruding portion 161P. The first region R1 may contact the printed circuit board (PCB) 110. The second region R2 may contact the first end portion of the signal terminal 141.

While this invention has been described in connection with what is presently considered to be practical embodiments, it is to be understood that the invention is not limited to the disclosed embodiments, but, on the contrary, is intended to cover various modifications and equivalent arrangements included within the scope of the appended claims.

What is claimed is:

1. A semiconductor module, comprising:
a printed circuit board;
a plurality of tab terminals on the printed circuit board, wherein the plurality of tab terminals comprise a plurality of signal terminals and a plurality of ground terminals, wherein the plurality of tab terminals are arranged in a first direction along a first edge of the printed circuit board, wherein each of the plurality of tab terminals extends in a second direction that is transverse to the first direction, and wherein each of the plurality of signal terminals comprises a first end portion adjacent to the first edge of the printed circuit board; and
a plurality of insulation members on the printed circuit board, wherein each of the plurality of insulation members covers the first end portion of a respective one of the plurality of signal terminals.

2. The semiconductor module of claim 1, wherein the plurality of ground terminals are spaced apart from the plurality of insulation members.

3. The semiconductor module of claim 1, wherein the plurality of tab terminals further comprise one or more power terminals.

4. The semiconductor module of claim 3, wherein the one or more power terminals are spaced apart from the plurality of insulation members.

5. The semiconductor module of claim 1, wherein the plurality of insulation members comprise a photo solder resist (PSR).

6. The semiconductor module of claim 1, wherein the plurality of insulation members comprise an overcoating material.

7. The semiconductor module of claim 6, wherein:
the overcoating material comprises polyurethane acrylate, urethane acrylate, acryl(Acrylic), modified acrylate, or epoxy.

8. The semiconductor module of claim 1, wherein:
each of the plurality of insulation members comprises a first region and a second region;
the first region contacts the printed circuit board; and
the second region contacts the first end portion of a respective one of the plurality of signal terminals.

9. The semiconductor module of claim 8, wherein:
a surface of the first region is located at a first level relative to a surface of the printed circuit board;
a surface of the second region is located at a second level relative to the surface of the printed circuit board; and
the second level is further outward from the surface of the printed circuit board than the first level.

10. The semiconductor module of claim 1, wherein:
each of the plurality of signal terminals comprises a first exposed surface, and each of the plurality of ground terminals comprises a second exposed surface; and
a distance in the second direction from the first edge of the printed circuit board to the first exposed surface is greater than a distance in the second direction from the first edge of the printed circuit board to the second exposed surface.

11. A semiconductor module, comprising:
a printed circuit board;
a plurality of tab terminals on the printed circuit board, wherein the plurality of tab terminals comprise a plurality of signal terminals and a plurality of ground terminals, wherein the plurality of tab terminals are arranged in a first direction along a first edge of the printed circuit board, wherein each of the plurality of tab terminals extends in a second direction that is transverse to the first direction, wherein each of the plurality of signal terminals comprises a first end portion adjacent to the first edge of the printed circuit board; and
an insulation member on the printed circuit board, wherein the insulation member comprises an extension portion extending in the first direction along the first edge of the printed circuit board, and a plurality of protruding portions extending in the second direction from the extension portion, and wherein each of the plurality of protruding portions covers the first end portion of a respective one of the plurality of signal terminals.

12. The semiconductor module of claim 11, wherein the plurality of ground terminals are spaced apart from the plurality of protruding portions.

13. The semiconductor module of claim 11, wherein the extension portion extends along the first edge of the printed circuit board between the plurality of tab terminals.

14. The semiconductor module of claim 11, wherein the extension portion is spaced apart from the plurality of tab terminals.

15. The semiconductor module of claim 11, wherein:
each one of the plurality of protruding portions comprises a first region and a second region;
the first region contacts the printed circuit board;
the second region contacts the first end portion of a respective one of the plurality of signal terminals.

16. A semiconductor module, comprising:
a printed circuit board;
a plurality of semiconductor chips on the printed circuit board;
a plurality of tab terminals on the printed circuit board, wherein the plurality of tab terminals comprise a plurality of signal terminals electrically connected to the plurality of semiconductor chips, and a plurality of ground terminals connected to a ground, wherein the plurality of tab terminals are arranged in a first direction along a first edge of the printed circuit board, wherein each of the plurality of tab terminals extends in a second direction that is transverse to the first direction and wherein each of the plurality of signal terminals comprises a first end portion adjacent to the first edge of the printed circuit board;
a plurality of first tie-bars on the printed circuit board, wherein each of the plurality of first tie-bars extends from a respective one of the plurality of signal terminals;
a plurality of second tie-bars on the printed circuit board, wherein each of the plurality of second tie-bars extends from a respective one of the plurality of ground terminals; and
a plurality of insulation members on the printed circuit board, wherein each of the plurality of insulation members covers the first end portion and the first tie-bar of a respective one of the plurality of signal terminals.

17. The semiconductor module of claim 16, wherein the plurality of first tie-bars and the plurality of second tie-bars extend in the second direction.

18. The semiconductor module of claim 17, wherein the plurality of first tie-bars and the plurality of second tie-bars extend to the first edge of the printed circuit board.

19. The semiconductor module of claim 16, wherein the plurality of ground terminals are spaced apart from the plurality of insulation members.

20. The semiconductor module of claim 19, wherein the plurality of second tie-bars are spaced apart from the plurality of insulation members.
